(19) United States
(12) Patent Application Publication
(10) Pub. No.: US 2025/0236823 A1
(43) Pub. Date: Jul. 24, 2025

(54) PHOTORESIST CLEANING COMPOSITION AND METHOD OF FORMING PHOTORESIST PATTERN USING THE SAME

(71) Applicant: DONGWOO FINE-CHEM CO., LTD., Jeollabuk-do (KR)

(72) Inventors: GI JIN KWUN, Jeollabuk-do (KR); BAEK HYUN CHO, Jeollabuk-do (KR)

(21) Appl. No.: 19/021,409

(22) Filed: Jan. 15, 2025

(30) Foreign Application Priority Data
Jan. 23, 2024 (KR) 10-2024-0010188
Apr. 16, 2024 (KR) 10-2024-0050662

(51) Int. Cl. C11D 7/50; C11D 7/26; G03F 7/42; H01L 21/02

(52) U.S. Cl. CPC C11D 7/5022; C11D 7/261; G03F 7/422; H01L 21/02057

(57) ABSTRACT

A photoresist cleaning composition includes a monoalcohol solvent and a polyhydric alcohol compound. A content of the polyhydric alcohol compound is greater than 0 ppm and 150 ppm or less based on a total weight of the composition. When using the photoresist cleaning composition including the monoalcohol solvent and the polyhydric alcohol compound, collapse of a photoresist pattern may be prevented, line width roughness may be improved, and uniformity of the photoresist pattern may be improved.

### CROSS REFERENCE TO RELATED APPLICATIONS AND CLAIM OF PRIORITY

This application claims the benefit under 35 USC § 119 of Korean Patent Application Nos. 10-2024-0010188 filed on Jan. 23, 2024 and 10-2024-0050662 filed on Apr. 16, 2024 in the Korean Intellectual Property Office, the entire disclosure of which are incorporated herein by reference for all purposes.

### BACKGROUND

### 1. Field of the Invention

The present invention relates to a photoresist cleaning composition and a method of forming a photoresist pattern using the same.

### 2. Description of the Related Art

Photoresist refers to a chemical film which is capable of forming a fine pattern printed on a photomask on a desired substrate using a photochemical reaction by light. The photoresist is a polymer material applied to an exposure technique along with a photomask, and is recognized as a major factor in a degree of integration and a resolution of a device. Recently, as a semiconductor device has been more highly integrated and miniaturized, development of a photoresist capable of fine patterning is required.

In the fine patterning technique using the photoresist, a field that is becoming important along with the development of a new photoresist is a cleaning solution for a semiconductor substrate. In order to form a high-resolution pattern, residues remaining on the semiconductor substrate should be removed through a cleaning process by the cleaning solution after exposure and development processes for the applied photoresist.

For example, the remaining photoresist film can be removed by spraying distilled water from an upper portion a spin device while spinning the semiconductor substrate. In this case, since the distilled water has a high surface tension, the pattern may be collapsed.

Therefore, a cleaning composition which may have excellent removal power against the residues generated after the exposure and development processes, and improve the resolution and uniformity of the pattern is required.

Korean Patent Registration Publication No. 10-1376340 discloses a composition for cleaning a semiconductor substrate. However, a cleaning composition for improving the resolution and uniformity of the pattern is still required.

### SUMMARY

An object of the present invention is to provide a photoresist cleaning composition capable of preventing collapse of a photoresist pattern and improving line width roughness.

Another object of the present invention is to provide a method of forming a photoresist pattern using the cleaning composition.

To achieve the above objects, the following technical solutions are adopted in the present invention.
1. A photoresist cleaning composition including: a monoalcohol solvent; and a polyhydric alcohol compound, wherein a content of the polyhydric alcohol compound is greater than 0 ppm and 150 ppm or less based on a total weight of the composition.
2. The photoresist cleaning composition according to the above 1, wherein the content of the polyhydric alcohol compound is greater than 0 ppm and 100 ppm or less based on the total weight of the composition.
3. The photoresist cleaning composition according to the above 1, wherein the monoalcohol solvent includes an alkyl alcohol having 2 to 5 carbon atoms.
4. The photoresist cleaning composition according to the above 1, wherein the monoalcohol solvent includes an alkyl alcohol having a boiling point of 120° C. or lower.
5. The photoresist cleaning composition according to the above 1, wherein the polyhydric alcohol compound includes a diol compound having two hydroxyl groups.
6. The photoresist cleaning composition according to the above 5, wherein the diol compound includes an alkyldiol compound having 2 to 5 carbon atoms.
7. The photoresist cleaning composition according to the above 5, wherein the diol compound includes a diol compound to which hydroxyl groups are bonded at both ends thereof.
8. The photoresist cleaning composition according to the above 5, wherein two hydroxyl groups of the diol compound are respectively bonded to carbon atoms adjacent to each other.
9. The photoresist cleaning composition according to the above 5, wherein two hydroxyl groups of the diol compound are bonded to one carbon atom.
10. The photoresist cleaning composition according to the above 1, wherein the polyhydric alcohol compound includes no polyol compound having three or more hydroxyl groups.
11. The photoresist cleaning composition according to the above 1, the photoresist cleaning composition includes no acidic compound or alkaline compound.
12. A method of forming a photoresist pattern, including: forming a photoresist film on a substrate; partially removing the photoresist film to form a photoresist pattern; and cleaning the substrate on which the photoresist pattern is formed using the photoresist cleaning composition according to the above 1.

The photoresist cleaning composition according to the embodiments of the present invention may include a monoalcohol solvent and a polyhydric alcohol compound. The content of the polyhydric alcohol compound may be controlled within a predetermined range. A photoresist pattern with improved uniformity may be implemented by the polyhydric alcohol compound having the controlled content.

In some embodiments, the polyhydric alcohol compound may include a diol compound having two hydroxyl groups. The undeveloped photoresist may be efficiently removed without collapse phenomenon of the pattern by the diol compound. Therefore, a decrease in the yield of a semiconductor device may be improved.

### BRIEF DESCRIPTION OF THE DRAWINGS

The above and other objects, features and other advantages of the present invention will be more clearly understood from the following detailed description taken in conjunction with the accompanying drawings, in which:

FIGS. 1 to 4 are schematic cross-sectional views for describing a method of forming a photoresist pattern according to exemplary embodiments.

### DETAILED DESCRIPTION OF THE INVENTION

According to exemplary embodiments of the present invention, a photoresist cleaning composition which includes a monoalcohol solvent and a polyhydric alcohol compound having a controlled content is provided. In addition, a method of forming a photoresist pattern using the cleaning composition is provided.

As used herein, the “alkyl” includes a straight-chain hydrocarbon and a branched-chain hydrocarbon. For example, alkyl having 4 carbon atoms may include n-butyl, isobutyl, sec-butyl and tert-butyl.

Hereinafter, embodiments of the present invention will be described in detail.

### <Photoresist Cleaning Composition>

The photoresist cleaning composition according to exemplary embodiments may include a monoalcohol solvent and a polyhydric alcohol compound having a controlled content.

The cleaning composition may remove, for example, process residues such as undeveloped photoresist or residual developer existing on a semiconductor substrate. For example, a polyhydric alcohol compound including two or more hydroxyl groups may additionally provide activity to organic and inorganic residues existing between photoresist patterns after exposure and development, thereby effectively removing the residues from the semiconductor substrate.

The monoalcohol solvent may include an organic solvent including one hydroxyl group.

The monoalcohol solvent may remove, for example, the developer and photoresist residues after the development process, and prevent collapse of the photoresist pattern during a drying process.

The monoalcohol solvent may include, for example, alkyl alcohols including 1-propanol, 2-propanol, 1-butanol, 2-butanol, isobutanol, tert-butanol, 1-pentanol, 2-pentanol, 3-pentanol, 1-hexanol, 2-hexanol, 3-hexanol, 1-heptanol, 2-heptanol, 3-heptanol, etc.; alkenyl alcohols including 4-penten-1-ol, 5-hexen-1-ol, 6-henten-1-ol, 7-octen-1-ol, 8-nonen-1-ol, 9-decen-1-ol, etc.

According to exemplary embodiments, the monoalcohol solvent may include an alkyl alcohol.

According to exemplary embodiments, the monoalcohol solvent may include an alkyl alcohol having 2 to 5 carbon atoms.

For example, the alkyl alcohol having 2 to 5 carbon atoms may include ethanol, 1-propanol, 2-propanol, 1-butanol, 2-butanol, isobutanol, tert-butanol, 1-pentanol, 2-pentanol, 3-pentanol, 3-methyl-1-butanol, 3-methyl-2-butanol, 2-methyl-1-butanol, 2-methyl-2-butanol, tert-amyl alcohol and the like.

For example, as the crude oil before purification, 2-propanol may be used as an alcohol solvent derived from fossil resources such as coal, oil, and natural gas, etc., and 2-propanol (bio-2-propanol) derived from biomass may be used.

Examples of bio-2-propanol may include 2-propanol obtained by using bacteria which produce 2-propanol from a biomass raw material (see International Patent Publication No. 2009/008377), 2-propanol obtained by hydrating propylene acquired by using biomethanol, 2-propanol obtained by reducing acetone acquired by using bioethanol, and 2-propanol obtained by hydrating propylene acquired by using bioethanol.

For example, if the number of carbon atoms in the alkyl alcohol is less than 2, stability is reduced due to high volatility, and undeveloped photoresist residues may not be removed. If the number of carbon atoms in the alkyl alcohol is greater than 5, due to the high boiling point, the monoalcohol solvent may remain on the substrate and dissolve the photoresist pattern, thereby causing a damage to the photoresist pattern.

For example, the monoalcohol solvent may include a single solvent or a mixed solvent of the above-described solvents.

In some embodiments, the monoalcohol solvent may include one or more selected from the group consisting of ethanol, 1-propanol, 2-propanol, 1-butanol and 1-pentanol.

In some embodiments, the monoalcohol solvent may include two or more selected from the group consisting of ethanol, 1-propanol, 2-propanol, 1-butanol and 1-pentanol.

For example, the monoalcohol solvent may include 30 to 70% by weight (“wt %”) of one selected from the group consisting of ethanol, 1-propanol, 2-propanol, 1-butanol and 1-pentanol based on a total weight of the monoalcohol solvent, and may include another one selected from the group consisting of ethanol, 1-propanol, 2-propanol, 1-butanol and 1-pentanol. For example, the monoalcohol solvent may include 50 wt % of 2-propanol based on the total weight of the monoalcohol solvent, and 1-butanol as a balance.

The monoalcohol solvent may be included as an extra or balance. The term “extra” or “balance” as used herein may refer to a variable amount which varies depending on addition of a component or formulation.

In some embodiments, the monoalcohol solvent may include an alkyl alcohol having a boiling point of 120° C. or lower. For example, the monoalcohol solvent may have a boiling point of 110° C. or lower.

For example, the monoalcohol solvent may have a vapor pressure of 0.3 kPa or more at 25° C. For example, the monoalcohol solvent may have a vapor pressure of 0.5 kPa or more at 25° C.

For example, the monoalcohol solvent may include one or more of 1-propanol, 2-propanol and 1-butanol. When the boiling point and the vapor pressure at room temperature satisfy the above ranges, the solvent may not remain on the substrate after the cleaning process.

The polyhydric alcohol compound may include an organic solvent including two or more hydroxyl groups.

The polyhydric alcohol compound may selectively remove, for example, photoresist residues or a developer. Therefore, the uniformity of the photoresist pattern may be improved.

The polyhydric alcohol compound may include, for example, diols including 1,1-dihydroxyethane, 1,2-dihydroxyethane, 1,1-dihydroxypropane, 1,2-dihydroxypropane, 1,3-dihydroxypropane, 1,1-dihydroxybutane, 1,2-dihydroxybutane, 1,3-dihydroxybutane, 1,4-dihydroxybutane, 1,1-dihydroxypentane, 1,2-dihydroxypentane, 1,3-dihydroxypentane, 1,4 dihydroxypentane, 1,5-dihydroxypentane, 1,1-dihydroxyhexane, 1,2-dihydroxyhexane, etc.; triols including 1,2,3-butanetriol, 1,2,4-butanetriol, 1,2,5-pentanetriol, 1,3,5-pentanetriol, 1,2,6-hexanetriol, trimethylolpropane, glycerin, etc.; tetraols including diglycerin, pentaerythritol, etc.;

According to exemplary embodiments, the polyhydric alcohol compound may include a diol compound having two hydroxyl groups.

According to exemplary embodiments, the polyhydric alcohol compound may include an alkyldiol compound having 2 to 5 carbon atoms.

For example, if the number of carbon atoms in the alkyldiol compound is less than 2, the ability to remove photoresist residues may be decreased, such that a uniform pattern may not be implemented. For example, if the number of carbon atoms in the alkyldiol compound is greater than 5, the solubility of the photoresist may be increased, such that the photoresist pattern may be damaged or the line width roughness may be increased.

The ability to remove the residues of the cleaning composition may vary depending on the hydroxyl group bonding position, bonding structure, etc. of the diol compound.

In some embodiments, the diol compound may include a diol compound to which hydroxyl groups are bonded at both ends thereof.

For example, a compound to which hydroxyl groups are bonded at both ends of a straight or branched hydrocarbon chain may be included in the diol compound. For example, 1,2-dihydroxyethane, 1,3-dihydroxypropane, etc. may be included in the diol compound.

The diol-based compound to which hydroxyl groups are bonded at both ends thereof may reduce the collapse phenomenon of the photoresist pattern.

In some embodiments, the alkyldiol compound may include no alkyldiol compound having 4 or more or 5 or more carbon atoms and to which hydroxyl groups are bonded at both ends thereof.

The alkyldiol compound to which hydroxyl groups are bonded at both ends thereof and having the number of carbon atoms within the above range or more may have a reduced selectivity to remove residues or developer due to a structure of the compound, thereby causing a damage to the photoresist pattern or a decrease in the line width uniformity.

In some embodiments, the diol compound may include an alkyldiol compound in which two hydroxyl groups are respectively bonded to carbon atoms adjacent to each other.

For example, the alkyldiol compound in which two hydroxyl groups are respectively bonded to carbon atoms adjacent to each other may include one or more of 1,2-dihydroxyethane, 1,2-dihydroxypropane, 1,2-dihydroxybutane and 1,2-dihydroxypentane.

In some embodiments, the diol compound may include an alkyldiol compound in which two hydroxyl groups are bonded to one carbon atom.

For example, the alkyldiol compound in which two hydroxyl groups are bonded to a common carbon atom may include one or more of 1,1-dihydroxyethane, 1,1-dihydroxypropane, 1,1-dihydroxybutane and 1,1-dihydroxypentane.

The diol compound in which two hydroxyl groups are respectively bonded to carbon atoms adjacent to each other or to one common carbon atom may reduce the line width roughness. Accordingly, it is possible to improve the uniformity of the photoresist film.

In some embodiments, the diol compound includes an alkyldiol compound having 4 to 5 carbon atoms, and may include an alkyldiol compound in which two hydroxyl groups are respectively bonded to carbon atoms not adjacent to each other.

For example, the alkyldiol compound in which two hydroxyl groups are respectively bonded to carbon atoms not adjacent to each other may include one or more of 1,3-dihydroxybutane, 1,3-dihydroxypentane and 1,4 dihydroxypentane. Here, the two hydroxyl groups may not be bonded to both ends.

In some embodiments, the polyhydric alcohol compound may include no polyol compound having three or more hydroxyl groups.

When three or more hydroxyl groups are included, the ability to capture the undeveloped photoresist residues or developer residues may be decreased, thereby increasing the line width roughness of the fine pattern.

According to exemplary embodiments, a content of the polyhydric alcohol compound may be greater than 0 ppm and 150 ppm or less based on a total weight of the composition.

In some embodiments, the content of the polyhydric alcohol compound may be greater than 0 ppm and 100 ppm or less, 0.01 ppm or more and 100 ppm or less, or 0.01 ppm or more and 50 ppm or less based on the total weight of the composition.

Within the above content range, the undeveloped photoresist residues may be removed without collapse phenomenon of the pattern, and the line width roughness of the photoresist pattern may be improved.

For example, if the content of the polyhydric alcohol compound is less than the above range, a removal amount of the undeveloped photoresist residue may be reduced, such that residues may exist on the substrate after cleaning. For example, if the content of the polyhydric alcohol compound is greater than the above range, the fine pattern may be dissolved, thereby pattern collapse may occur.

According to exemplary embodiments, the cleaning composition may also include water. For example, the content of the water may be 0.01 ppm or more and 50 ppm or less, or 0.1 ppm or more and 30 ppm or less.

According to exemplary embodiments, the cleaning composition may include no acidic compound or alkaline compound. The acidic compound or alkaline compound may be substantially not included. For example, a content of the acidic compound or alkaline compound may be 0.001 ppm or less. For example, when an acidic compound or a basic compound is included, activation of the photoresist due to hydrogen ions or hydroxide ions may occur, thereby resulting in a melting phenomenon of the photoresist pattern.

According to exemplary embodiments, the cleaning composition may further include an additional organic solvent. For example, ethylene glycol monomethyl ether, ethylene glycol monoethyl ether, ethylene glycol monoisopropyl ether, ethylene glycol monobutyl ether, diethylene glycol monomethyl ether, diethylene glycol monoethyl ether, diethylene glycol monoisopropyl ether, diethylene glycol monobutyl ether, dipropylene glycol monomethyl ether, propylene glycol monobutyl ether, dipropylene glycol monopropyl ether, ethylene glycol phenyl ether, propylene glycol monomethyl ether acetate, etc. may be further included, and these may be included alone or in combination of two or more thereof.

The cleaning composition may further include an additive as necessary. The additive may be included within a range that does not inhibit the performance of selectively removing the photoresist residues or developer residues of the polyhydric alcohol compound. For example, the cleaning composition may include a corrosion-resistant agent, etc.

### <Method of Forming Photoresist Pattern>

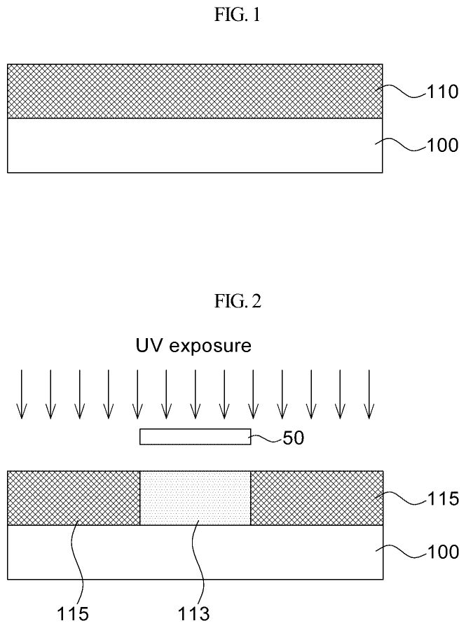

FIGS. 1 to 4 are schematic cross-sectional views for describing a pattern forming method according to exemplary embodiments. For example, FIGS. 1 to 4 illustrate a pattern forming process using a negative photoresist.

However, the cleaning composition according to exemplary embodiments is not limited to the process shown in FIGS. 1 to 4, and may also be utilized in a pattern forming process using a positive photoresist.

Referring to FIG. 1, a photoresist material may be coated on a substrate 100 to form a photoresist film 110.

The substrate 100 may include a semiconductor material such as single crystal silicon or single crystal germanium, and may also be formed to include polysilicon.

In some embodiments, a soft baking process may be performed after forming the photoresist film 110. Accordingly, an organic solvent that can be included in the photoresist film 110 may be evaporated. Referring to FIG. 2, a non-exposed portion 113 and an exposed portion 115 may be formed on the substrate 100 through an exposure process. The exposure process may be performed using a light source (e.g., an EUV light source) and an exposure mask 50.

Light (e.g., EUV) passing through the exposure mask 50 may be irradiated onto the photoresist film 110. Thereby, the photoresist film 110 may have the non-exposed portion 113 and the exposed portion 115.

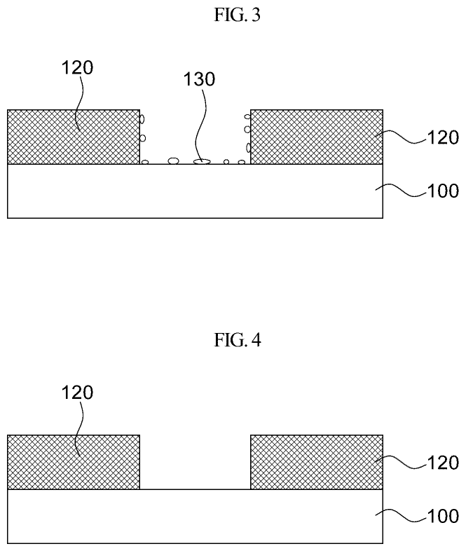

Referring to FIG. 3, a photoresist pattern 120 may be formed on the substrate 100 through a development process. For example, a developer may be used to remove the non-exposed portion 113 on the substrate 100 to form the photoresist pattern 120 composed of the exposed portion 115. The developer may be a tetramethylammonium hydroxide (TMAH) aqueous solution.

FIG. 3 illustrates a pattern forming process using a negative photoresist, but it is not limited thereto. For example, a pattern forming process using a positive photoresist may be performed, in this case, the exposed portion 115 may be removed and a photoresist pattern composed of the non-exposed portion 113 may be formed.

In some embodiments, a post-baking process may be further performed after the exposure process or after the development process.

After the formation process, a development residue 130 may exist on the substrate 100. The development residue 130 may be an undeveloped photoresist or a developer residue. As the development residue 130 remains on the substrate 100 or the photoresist pattern 120, a seam may be induced in the photoresist pattern 120, and the line width roughness of the pattern may be increased.

Referring to FIG. 4, the cleaning composition according to the above-described exemplary embodiments may be applied to or immersed on the substrate 100. Accordingly, the development residue 130 formed on the substrate 100 or the photoresist pattern 120 may be removed.

The cleaning step may be performed by applying the cleaning composition according to the above-described exemplary embodiments to the substrate 100 under cleaning conditions commonly known in the art.

In some embodiments, the temperature during cleaning may be 25° C. to 70° C., or 25° C. to 50° C. The residence time of the substrate 100 when immersed in the cleaning composition may be about 5 seconds to 10 minutes, or 10 seconds to 5 minutes.

In some embodiments, the cleaning step may be performed by performing a first cleaning using deionized water to remove developer residues, followed by a second cleaning using the cleaning composition according to the above-described exemplary embodiments.

As described above, as the cleaning composition includes the monoalcohol solvent and the polyhydric alcohol compound, undeveloped photoresist may be removed and a profile of the photoresist pattern 120 may be improved.

In addition, as the type, content, etc. of the polyhydric alcohol compound are controlled, only residues may be effectively removed without causing a damage to a structure (e.g., the photoresist pattern) included in the semiconductor device.

Accordingly, photoresist scum, and pattern collapse, etc. that occur during the formation of the fine pattern may be prevented, thereby improving the line width roughness of the pattern, and may be usefully used in the formation of a fine pattern using an extreme ultraviolet lithography (EUVL) technique.

Hereinafter, experimental examples including specific examples and comparative examples are proposed to facilitate understanding of the present invention. However, the following examples are only given for illustrating the present invention and are not intended to limit the appended claims. It will be apparent those skilled in the art that various alterations and modifications are possible within the scope and spirit of the present invention, and such alterations and modifications are duly included in the appended claims.

### Examples and Comparative Examples

Cleaning compositions of the examples and comparative examples, in which a sum of contents of each component was 100 wt %, were prepared by mixing the components described in Table 1 below in the corresponding contents.

TABLE 1

| | Polyhydric alcohol (wt ppm) | | | | | | | Organic solvent (wt %) | | | | | |
|---|---|---|---|---|---|---|---|---|---|---|---|---|---|
| Division | A-1 | A-2 | A-3 | A-4 | A-5 | A-6 | A-7 | B-1 | B-2 | B-3 | B-4 | B-5 | B-6 |
| Example | | 0.01 | | | | | | Balance | | | | | |
| 1 | | | | | | | | | | | | | |
| Example | | 1 | | | | | | Balance | | | | | |
| 2 | | | | | | | | | | | | | |
| Example | | 10 | | | | | | Balance | | | | | |
| 3 | | | | | | | | | | | | | |
| Example | | 50 | | | | | | Balance | | | | | |
| 4 | | | | | | | | | | | | | |
| Example | | 100 | | | | | | Balance | | | | | |
| 5 | | | | | | | | | | | | | |
| Example | | 120 | | | | | | Balance | | | | | |
| 6 | | | | | | | | | | | | | |
| Example | 10 | | | | | | | Balance | | | | | |
| 7 | | | | | | | | | | | | | |
| Example | | | 10 | | | | | Balance | | | | | |
| 8 | | | | | | | | | | | | | |
| Example | | | | 10 | | | | Balance | | | | | |
| 9 | | | | | | | | | | | | | |
| Example | | | | | 10 | | | Balance | | | | | |
| 10 | | | | | | | | | | | | | |
| Example | | 10 | | | | | | 50 | | | Balance | | |
| 11 | | | | | | | | | | | | | |
| Example | | | 10 | | | | | 50 | | | Balance | | |
| 12 | | | | | | | | | | | | | |
| Example | | 10 | | | | | | | Balance | | | | |
| 13 | | | | | | | | | | | | | |
| Example | | 10 | | | | | | | | Balance | | | |
| 14 | | | | | | | | | | | | | |
| Example | | 10 | | | | | | | | | Balance | | |
| 15 | | | | | | | | | | | | | |
| Example | | 10 | | | | | | | | | | Balance | |
| 16 | | | | | | | | | | | | | |
| Example | | 10 | | | | | | | | | | | Balance |
| 17 | | | | | | | | | | | | | |
| Example | | | | | | 10 | | Balance | | | | | |
| 18 | | | | | | | | | | | | | |
| Example | | | | | | | 10 | Balance | | | | | |
| 19 | | | | | | | | | | | | | |
| Comparative | | Balance | | | | | | | | | | | |
| Example | | (wt %) | | | | | | | | | | | |
| 1 | | | | | | | | | | | | | |
| Comparative | | | | Balance | | | | | | | | | |
| Example | | | | (wt %) | | | | | | | | | |
| 2 | | | | | | | | | | | | | |
| Comparative | | | | | | | | Balance | | | | | |
| Example | | | | | | | | | | | | | |
| 3 | | | | | | | | | | | | | |
| Comparative | | | | | | | | | | | Balance | | |
| Example | | | | | | | | | | | | | |
| 4 | | | | | | | | | | | | | |
| Comparative | | 200 | | | | | | Balance | | | | | |
| Example | | | | | | | | | | | | | |
| 5 | | | | | | | | | | | | | |

The specific component names of the polyhydric alcohol and organic solvent described in Table 1 above are as follows.

### Polyhydric Alcohol

A-1:1,2-dihydroxyethane
A-2:1,2-dihydroxypropane
A-3:1,3-dihydroxypropane
A-4:1,2-dihydroxybutane
A-5:1,2-dihydroxypentane
A-6:1,2-dihydroxyheptane
A-7: Glycerol
   Organic solvent
B-1:2-propanol
B-2:1-propanol
B-3: Ethanol
B-4:1-butanol
B-5:1-pentanol
B-6:1-heptanol

### Experimental Example

A lower antireflective film (DUV42P-6, Nissan Chemical Industries) was spin-coated on a silicon wafer, and then heated at 215° C. for 90 seconds to form a film having a thickness of 600 Å. A PHS-type photoresist (KTF-5664, Dongwoo Finechem) was spin-coated on an upper portion of the silicon wafer on which the film was formed to prepare a photoresist thin film, and then soft-baked in an oven at 100° C. for 60 seconds. Subsequently, the film was exposed using scanner equipment equipped with a KrF laser and post-baked in an oven at 110° C. for 60 seconds. Then, development was performed by immersing the film in a 2.38 wt % tetramethylammonium hydroxide (TMAH) aqueous solution for 60 seconds.

Thereafter, developer residues on the upper portion of the silicon wafer was removed using deionized water. 30 ml of the cleaning composition of each of the examples was applied to the surface of the washed silicon wafer for 10 seconds, and then dried by high-speed spinning to obtain a pattern with a 180 nm line and space (L/S) resolution.

### (1) Evaluation of Pattern Collapse

Collapse phenomenon of the 180 nm L/S pattern was observed using CD-SEM (Critical Dimension Scanning Electron Microscope, Hitachi). A phenomenon in which the pattern is collapsed was evaluated according to the following standards, and results thereof are shown in Table 2 below.

### <Standards for Evaluation>

o: Pattern collapse does not occur
Δ: Collapse phenomenon occurs only in an edge pattern
X: Collapse phenomenon occurs in the edge and central patterns

### (2) Evaluation of Line Width Roughness

A line width roughness value was confirmed by measuring a difference between the widest portion and the narrowest portion of the 180 nm L/S pattern using the CD-SEM (Hitachi), and results thereof are shown in Table 2 below. It means that the smaller line width roughness value, the more uniform pattern.

### (3) Evaluation of Photoresist Thickness Reduction

A difference in the photoresist thickness before and after treatment with the photoresist cleaning composition was measured using FE-SEM (Field-Emission Scanning Electron Microscope, Hitachi), and the degree of photoresist thickness reduction was confirmed. The photoresist thickness reduction was evaluated according to the following standards, and results thereof are shown in Table 2 below. It means that the smaller difference in the photoresist thickness, the less photoresist pattern is damaged.

### <Standards for Evaluation>

o: Difference in the photoresist thickness is 20 Å or less
Δ: Difference in the photoresist thickness is greater than 20 Å and 50 Å or less
x: Difference in the photoresist thickness is greater than 50 Å

TABLE 2

| | Evaluation of pattern | Evaluation of line | Evaluation of photoresist |
|---|---|---|---|
| Division | collapse | width roughness (nm) | thickness reduction |
| Example 1 | ◯ | 2.9 | ◯ |
| Example 2 | ◯ | 2.8 | ◯ |
| Example 3 | ◯ | 2.7 | ◯ |
| Example 4 | ◯ | 2.8 | ◯ |
| Example 5 | ◯ | 2.8 | ◯ |
| Example 6 | Δ | 2.9 | ◯ |
| Example 7 | Δ | 2.8 | ◯ |
| Example 8 | ◯ | 3.3 | ◯ |
| Example 9 | ◯ | 3.5 | ◯ |
| Example 10 | ◯ | 2.7 | ◯ |
| Example 11 | ◯ | 2.6 | ◯ |
| Example 12 | ◯ | 3.6 | ◯ |
| Example 13 | ◯ | 2.8 | ◯ |
| Example 14 | ◯ | 2.7 | ◯ |
| Example 15 | ◯ | 2.6 | ◯ |
| Example 16 | ◯ | 2.7 | ◯ |
| Example 17 | ◯ | 2.6 | Δ |
| Example 18 | ◯ | 2.7 | Δ |
| Example 19 | Δ | 5.2 | ◯ |
| Comparative | X | 5.1 | ◯ |
| Example 1 | | | |
| Comparative | X | 5.3 | ◯ |
| Example 2 | | | |
| Comparative | ◯ | 5.0 | ◯ |
| Example 3 | | | |
| Comparative | ◯ | 5.3 | ◯ |
| Example 4 | | | |
| Comparative | Δ | 3.2 | ◯ |
| Example 5 | | | |

Referring to Table 2 above, when the cleaning compositions according to the examples were used, the line width roughness and the difference in the photoresist thickness were reduced compared to the cleaning compositions according to the comparative examples, and the pattern collapse phenomenon was not observed.

When the cleaning composition of Example 17 including an organic solvent having greater than 5 carbon atoms was used, the difference in the photoresist thickness was greater than 20 Å and 50 Å or less.

When the cleaning composition of Example 18 including a polyhydric alcohol having greater than 5 carbon atoms was used, the difference in the photoresist thickness was greater than 20 Å and 50 Å or less.

When the cleaning composition of Example 19 including a polyhydric alcohol having greater than 2 hydroxyl groups was used, the collapse phenomenon occurred in the edge pattern.

When the cleaning compositions of Comparative Example 1 and Comparative Example 2 which do not include the organic solvent by using a polyhydric alcohol as a solvent were used, the collapse phenomena occurred in the edge pattern and the central pattern, and the line width roughness was greater than 5 nm.

When the cleaning compositions of Comparative Examples 3 and 4 which do not include the polyhydric alcohol were used, the line width roughness was greater than 5 nm.

When the cleaning composition of Comparative Example 5 including 200 ppm or more of polyhydric alcohol was used, the collapse phenomenon occurred in the edge pattern, and the line width roughness was greater than 3 nm.

What is claimed is:

1. A photoresist cleaning composition comprising:
a monoalcohol solvent; and
a polyhydric alcohol compound,
wherein a content of the polyhydric alcohol compound is greater than 0 ppm and 150 ppm or less based on a total weight of the composition.

2. The photoresist cleaning composition according to claim 1, wherein the content of the polyhydric alcohol compound is greater than 0 ppm and 100 ppm or less based on the total weight of the composition.

3. The photoresist cleaning composition according to claim 1, wherein the monoalcohol solvent comprises an alkyl alcohol having 2 to 5 carbon atoms.

4. The photoresist cleaning composition according to claim 1, wherein the monoalcohol solvent comprises an alkyl alcohol having a boiling point of 120° C. or lower.

5. The photoresist cleaning composition according to claim 1, wherein the polyhydric alcohol compound comprises a diol compound having two hydroxyl groups.

6. The photoresist cleaning composition according to claim 5, wherein the diol compound comprises an alkyldiol compound having 2 to 5 carbon atoms.

7. The photoresist cleaning composition according to claim 5, wherein the diol compound comprises a diol compound to which hydroxyl groups are bonded at both ends thereof.

8. The photoresist cleaning composition according to claim 5, wherein two hydroxyl groups of the diol compound are respectively bonded to carbon atoms adjacent to each other.

9. The photoresist cleaning composition according to claim 5, wherein two hydroxyl groups of the diol compound are bonded to one carbon atom.

10. The photoresist cleaning composition according to claim 1, wherein the polyhydric alcohol compound comprises no polyol compound having three or more hydroxyl groups.

11. The photoresist cleaning composition according to claim 1, the photoresist cleaning composition comprises no acidic compound or alkaline compound.

12. A method of forming a photoresist pattern, the method comprising:
forming a photoresist film on a substrate;
partially removing the photoresist film to form a photoresist pattern; and
cleaning the substrate on which the photoresist pattern is formed using the photoresist cleaning composition according to claim 1.
